(19) United States
(12) Patent Application Publication
(10) Pub. No.: US 2026/0191039 A1
(43) Pub. Date: Jul. 2, 2026

(54) PSEUDO-ANNULAR THRU-CORE METAL STRUCTURES FOR IMPROVED SIGNALING AND THERMAL MANAGEMENT METHODS OF FABRICATING

(71) Applicant: Intel Corporation, Santa Clara, CA (US)

(72) Inventors: Brandon Marin, Gilbert, AZ (US); Makoyi Watson, Phoenix, AZ (US); Duye Ye, Omaha, NE (US); Shriya Seshadri, Chandler, AZ (US); Jacob Vehonsky, Chandler, AZ (US); Jason Gamba, Gilbert, AZ (US)

(73) Assignee: Intel Corporation, Santa Clara, CA (US)

(21) Appl. No.: 19/005,407

(22) Filed: Dec. 30, 2024

(51) Int. Cl. H01L 23/538; H01L 21/48; H01L 23/15

(52) U.S. Cl. CPC H10W 70/611; H10W 70/095; H10W 70/635; H10W 70/65; H10W 70/692

(57) ABSTRACT

Microelectronic integrated circuit package structures include a core substrate, wherein the core substrate comprises a plurality of outer vias each extending through the layer of glass, wherein the outer vias each comprise a first lateral width, and wherein the outer vias each comprises individual annular segments separated by a distance; and one or more inner vias extending through the layer of glass adjacent to the outer vias, wherein the one or more inner vias comprise a second lateral width, wherein the first lateral width is greater than the second lateral width.

### BACKGROUND

In electronics manufacturing, integrated circuit (IC) packaging is a stage of manufacture where an IC that has been fabricated on a die or chip comprising a semiconducting material is coupled to a supporting case or “package” that can protect the IC from physical damage and support electrical interconnect suitable for further connecting to a host component, such as a printed circuit board (PCB). In the IC industry, the process of fabricating a package is often referred to as packaging, or assembly.

As semiconductor IC packaging architectures continue towards more complex and more compact systems, high signal input output (HSIO) structures in IC packages demand designs, processes and materials to minimize signal loss and maximize bandwidth at a desired operating frequency. One major signal loss in such HSIO structures is associated with through hole structures in a substrate core. Core structures can include conductive paths for a differential pair of signal structures with a ring of grounding through holes surrounding the signal structures to minimize capacitive losses. This ring of grounding through hole structures form an effective faraday cage, but its effectiveness is limited by how close the through hole structures can be placed to one another.

### BRIEF DESCRIPTION OF THE DRAWINGS

The subject matter described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIGS. 1A-1B are top views of annular through core conductive structures, in accordance with some embodiments.

FIG. 1C is a cross-sectional view of annular through core conductive structures, in accordance with some embodiments.

FIGS. 2A-2G are cross-sectional views of methods of forming annular through core conductive structures, in accordance with some embodiments.

FIGS. 3A-3F are cross-sectional views of methods of forming annular through core conductive structures, in accordance with some embodiments.

FIG. 4 is a cross-sectional view of an IC package structure comprising annular through core conductive structures, in accordance with some embodiments.

FIG. 5 illustrates a flow chart of a process for the fabrication of IC package structures having comprising annular through core conductive structures, in accordance with some embodiments.

FIG. 6 is a functional block diagram of an electronic computing device, in accordance with some embodiments of the present disclosure.

### DETAILED DESCRIPTION

Embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause and effect relationship).

The terms “over,” “under,” “between,” and “on” as used herein refer to a relative position of one component or material with respect to other components or materials where such physical relationships are noteworthy. For example in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct physical contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the explicit context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent.

The term “package” generally refers to a self-contained carrier of one or more dice, where the dice are attached to the package substrate, and may be encapsulated for protection, with integrated or wire-bonded interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

The term “dielectric” generally refers to any number of non-electrically conductive materials that make up the structure of a package substrate.

The term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

The term “bond pad” generally refers to metallization structures that terminate integrated traces and vias in integrated circuit packages and dies. The term “solder pad” may be occasionally substituted for “bond pad” and carries the same meaning.

The term “solder bump” generally refers to a solder layer formed on a bond pad. The solder layer typically has a round shape, hence the term “solder bump”.

The term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

Views labeled “cross-sectional”, “profile” and “plan” correspond to orthogonal planes within a Cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

Embodiments discussed herein address problems associated with reducing capacitive loss at a desired operating frequency in HSIO packaging architectures. Through glass vias (TGV)'s can be used to provide conductive paths for differential signal pairs in a substrate core with a ring of grounding TGV's providing a faraday cage to reduce capacitive loss. However, the effectiveness of such a faraday cage is limited due to limitations in how close the grounding TGV's can be placed next to each other. Methods described herein utilize glass core substrate processing to form segmented annular ring TGV grounding structures which minimize loss and maximize bandwidth at a desired operating frequency.

For example, glass core package structures utilizing grounding TGV segmented annular structures described herein enable less than 1 dB loss for a glass core substrate at 90 GHz. In embodiments, the segmented annular ring TGV ground structures may surround HSIO TGV signal structures to form a faraday cage. The embodiments result in a decrease in signal loss due to a reduction of spacing between the annular ring ground structures.

The architectures described herein may be assembled and/or fabricated with one or more of the features or attributes provided in accordance with various embodiments. A number of different assembly and/or fabrication methods may be practiced to enable the formation of glass core package structures which prevent loss and improve thermal conductivity.

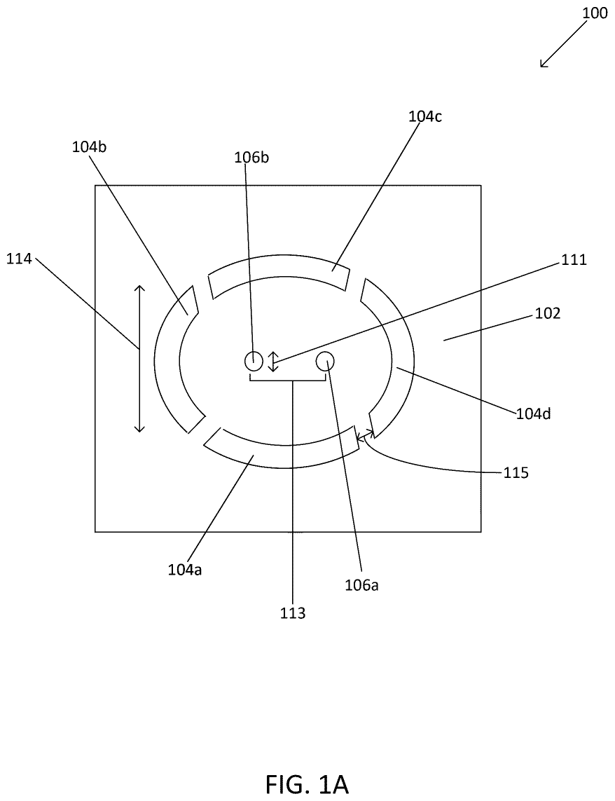

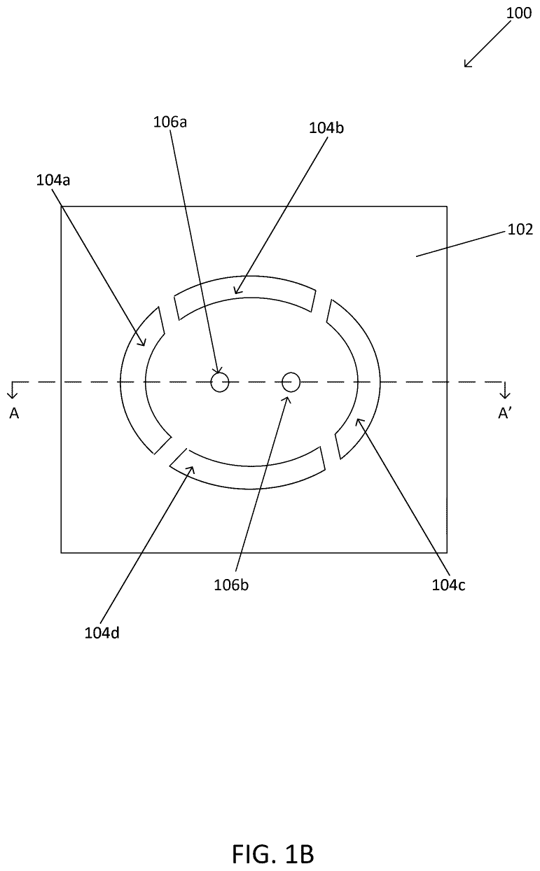

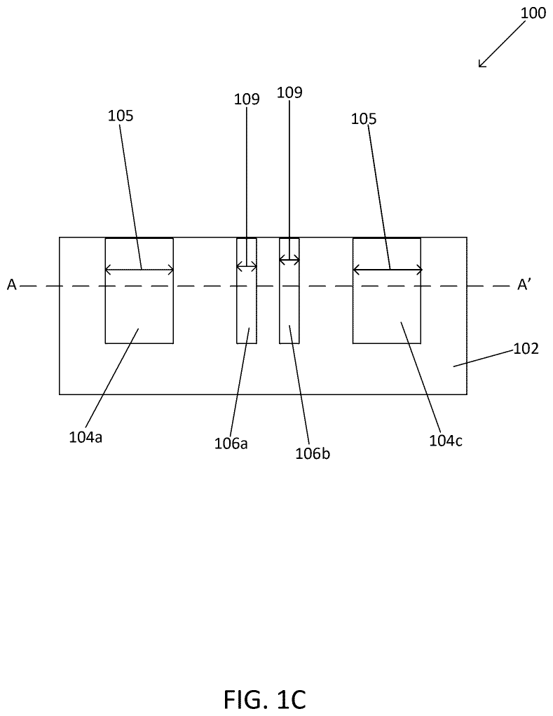

FIGS. 1A-1C illustrate embodiments of forming segmented annular ring ground structures surrounding differential signal structures within a glass core substrate to form glass core package structures which reduce signal loss in IC package structures. The package structures may be formed utilizing standard IC processing techniques. The methods of fabrication described herein create improved device performance in advanced 2.5D and 3D packaging.

FIG. 1A is a top view of a portion of a package substrate comprising a core substrate 102 which may include buildup layers (not shown) on top surfaces and bottom surfaces of the core substrate 102. In an embodiment, the core substrate 102 may comprise a layer of glass. In an embodiment, the core substrate 102 may comprise substantially all glass or may comprise a layer of glass. The core substrate 102 may be a solid material with an amorphous crystal structure. More particularly, the core substrate 102 may be any suitable glass formulation that has the necessary mechanical robustness and compatibility with semiconductor packaging manufacturing and assembly processes. For example, the core substrate 102 may comprise aluminosilicate glass, borosilicate glass, alumino-borosilicate glass, silica, fused silica, or the like. In some embodiments, the core substrate may include one or more additives, such as, but not limited to, Al2O3, B2O3, MgO, CaO, SrO, BaO, SnO2, Na2O, K2O, SrO, P2O3, ZrO2, Li2O, Ti, and Zn.

More generally, the core substrate 102 may comprise silicon and oxygen, as well as any one or more of aluminum, boron, magnesium, calcium, barium, tin, sodium, potassium, strontium, phosphorus, zirconium, lithium, titanium, and zinc. In an embodiment, the core substrate 102 may comprise at least 23 percent silicon (by weight) and at least 26 percent oxygen (by weight). In some embodiments, the core substrate 102 may further comprise at least 5 percent aluminum (by weight).

In an embodiment, the core substrate 102 may have a thickness (between a first side and second side) that is between approximately 500 microns and approximately 1,000 microns, although the thickness may be optimized for the particular application. The core substrate 102 may have a substantially rectangular shape (when viewed from above in a plan view), although, other shapes may also be used for the core substrate 102.

One or more inner vias 106a and 106b are in a central portion of the core substrate 102. The one or more inner vias 106a, 106b may comprise a pair of differential signal structures. In an embodiment, the one or more inner vias 106a, 106b comprise one or more inner through glass vias (TGV)s 106a, 106b where the one or more inner TGVs extend from a top surface of the core substrate 102 to a bottom surface of the core substrate 102 and may be filled with a conductive material, such as copper or a copper alloy, for example. In an embodiment, the one or more inner TGVs 106a, 106b may comprise a distance 113 between a first inner TGV 106a and a second inner TGV 106b, wherein the distance 113 is between 80 microns and 200 microns. In an embodiment, the one or more inner TGVs 106a, 106b comprise a circular shape and may comprise a diameter 111 of between 80-200 microns.

One or more outer TGVs 104a-104d may surround the one or more inner TGVs 106a, 106b. The one or more outer TGVs 104a-104d may comprise segmented annular rings surrounding the one or more inner TGVs 106a, 106b. In an embodiment, a length 114 of individual segments of the one or more outer TGV's 104 a-104d may be between 200 microns and 1000 microns. A distance 115 may be between individual segments (for example between segment 104a and segment 104b) of the one or more outer TGVs.

The distance 115 between individual ones of the one or more outer TGVs 104a-104d may comprise between 10 microns and 50 microns but may vary depending upon the particular design. The one or more inner TGVs 106a, 106b surrounded by the one or more outer TGVs 104a-104d may comprise a portion of a HSIO device 100 in which the segmented annular thru-core metal structures provide improved signaling and thermal management for device performance.

FIG. 1B is a top view of a portion of an IC package structure 100 where a segment A-A′ is cut through to show the cross-sectional portion in FIG. 1C. FIG. 1C depicts a cross-sectional view of package structure 100 through segment A-A′ including outer TGVs 104a, 104c and inner TGVs 106a, 106b. The TGVs 104a, 104c comprise a lateral width 105 which is greater than a lateral width 109 of the inner TGVs 106a, 106b. In an embodiment, the lateral width 105 of the outer TGVs 104a, 104c may comprise greater than twice the lateral width 109 of the inner TGVs 106a, 106b. The lateral widths 105, 109 of the inner TGVs 106a, 106b and the outer TGVs 104a, 104c may be optimized for a particular design, however the lateral widths 105 of the outer TGVs are greater in general than the lateral widths 109 of the inner TGVs.

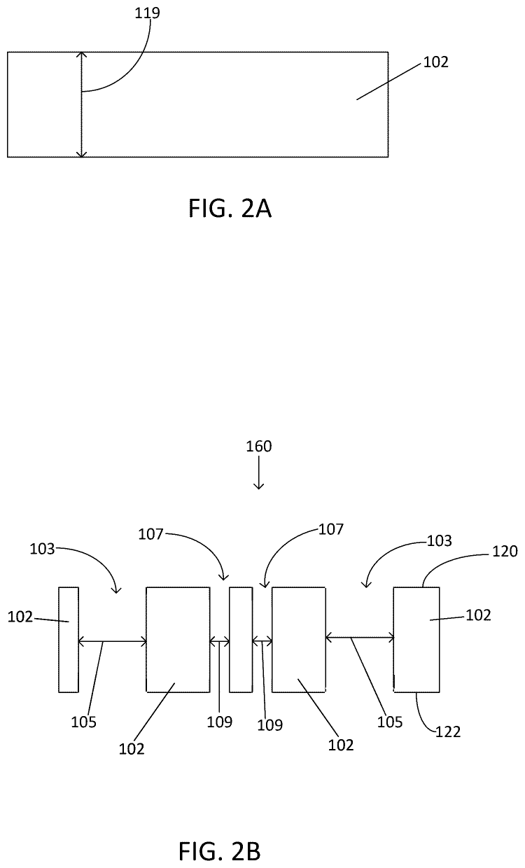

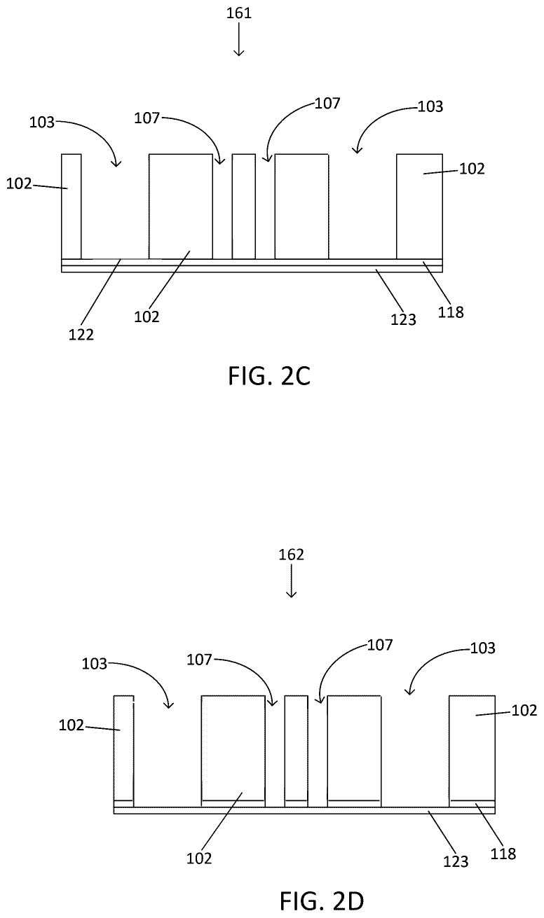

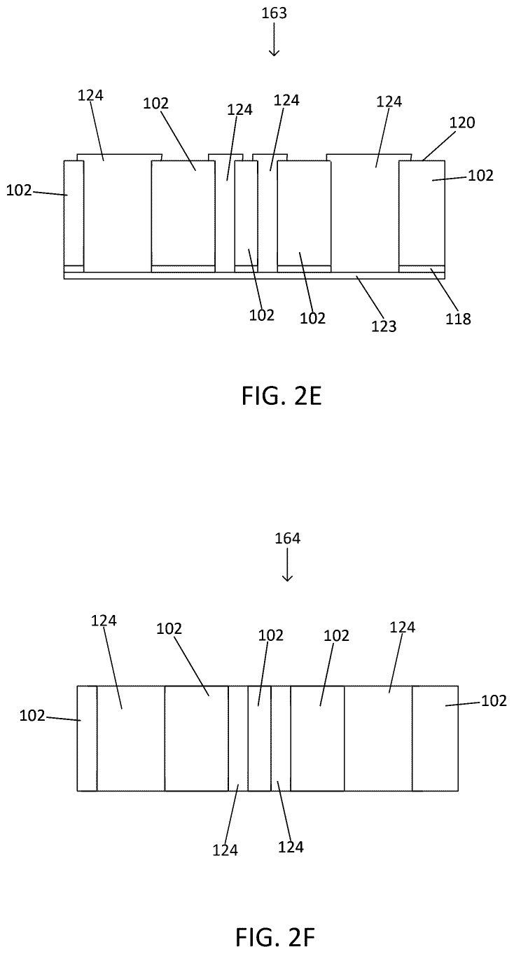

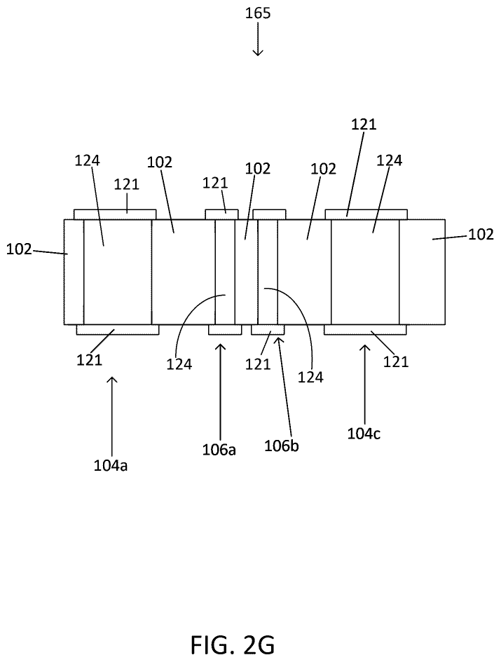

FIGS. 2A-2G depict methods of forming annular through core metal ground structures which surround circular thru-core metal signal structures to form IC package devices by utilizing a bottom-up plating process of glass core through hole structures for example. A faraday cage structure is formed having near zero spacing between individual segmented ground TGVs.

FIG. 2A depicts a cross-sectional view of a portion of a core substrate 102 comprising a layer of glass. In an embodiment, the core substrate 102 may comprise a thickness 119 of between 500 microns to 1000 microns. In FIG. 2B, a process 160 may be employed wherein a plurality of first openings 103 may be formed and a plurality of second openings 107 may be formed. A first lateral width 105 of the first openings 103 may be greater than a second lateral width 109 of the second openings 107. In an embodiment, the first lateral width 105 may comprise 80 microns to 200 microns, and the second lateral width 109 may comprise 80 to 200 microns. In an embodiment, the process 160 may comprise any suitable etching process to remove glass, such as a laser removal process for example. The first openings 103 and the second openings 107 extend through the core substrate 102 between a first side 120 and a second side 122 of the core substrate 102.

FIG. 2C depicts a cross-sectional view of a process 161, wherein a first layer 118 is formed on the second side 122 of the core substrate 102, and a second layer 123 is formed on the first layer 118. In an embodiment, the first layer 118 comprises an adhesive material such as a film comprising a filler and a resin, such as a die attach film, for example, and may comprise a thickness of between 1-3 microns. In an embodiment, the second layer 123 may comprise a conductive material, such as copper or copper alloys. In an embodiment, the second layer 123 may comprise a thin copper foil, and may comprise a thickness of between 1 micron and 3 microns.

FIG. 2D depicts a process 162 wherein portions of the first layer 118 are removed and portions of the second layer 123 are exposed. In an embodiment, the first layer 118 may be removed by utilizing a reactive ion etch (RIE) process 162 which exposes the second layer 123 between the openings 103, 107.

FIG. 2E depicts a formation process 163 wherein a conductive material 124 is formed within the first openings 103 and the second openings 107. In an embodiment, the conductive formation process 163 may comprise an electrolytic plating process 163. In an embodiment, the conductive material 124 may be formed a distance above the first side 120 of the core substrate 102. In an embodiment, the conductive material 124 may comprise any suitable conductive material such as copper or copper alloys, for example.

FIG. 2F depicts a planarization process 164 wherein the excess conductive material 124 that is above the surface 120 of the core substrate 102 is removed so that the surface of the conductive material 124 is coplanar with the surface of the core substrate 102. In an embodiment, the planarization process 164 may comprise a chemical mechanical polishing (CMP) process, or any other suitable process may be used to planarize the conductive material 124. Additionally, the first layer 118 and the second layer 123 may be removed from the second side 122 of the core substrate 102.

FIG. 2G depicts a contact formation process 165 wherein a self-aligned patterning and etching process may be employed to form contact structures 121 on the surfaces of the conductive material 124. In this manner, outer TGV structures 104a, 104c surrounding inner TGV structures 106a, 106b may be formed, similar to those depicted in FIG. 1C for example. Due to the larger size of the outer TGV structures 104a, 104c relative to the inner TGV structures 106a, 106b, thermal conductivity is improved within the core substrate 102. Thermal transport in x-y and z-directions is improved within package structures utilizing the TGV structures of the embodiments herein. Additionally, since the segmented annular TGV structures replace more of the glass core substrate 102, the core substrate 102 exhibits superior thermal conductivity.

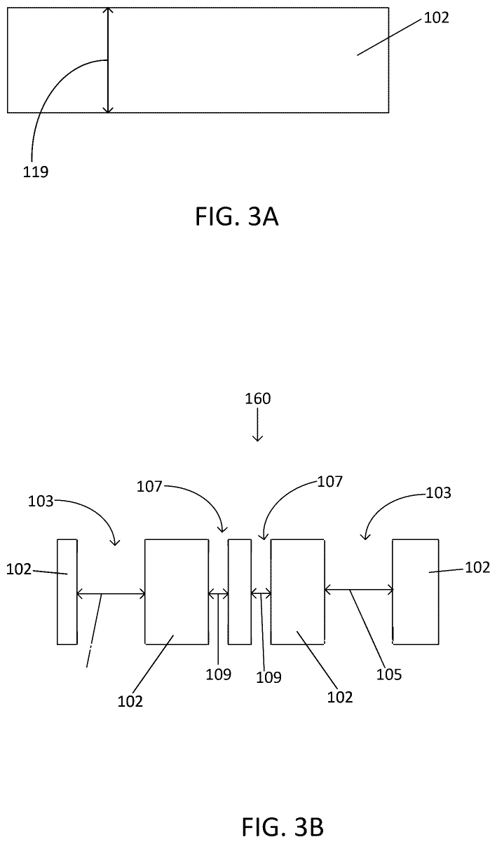

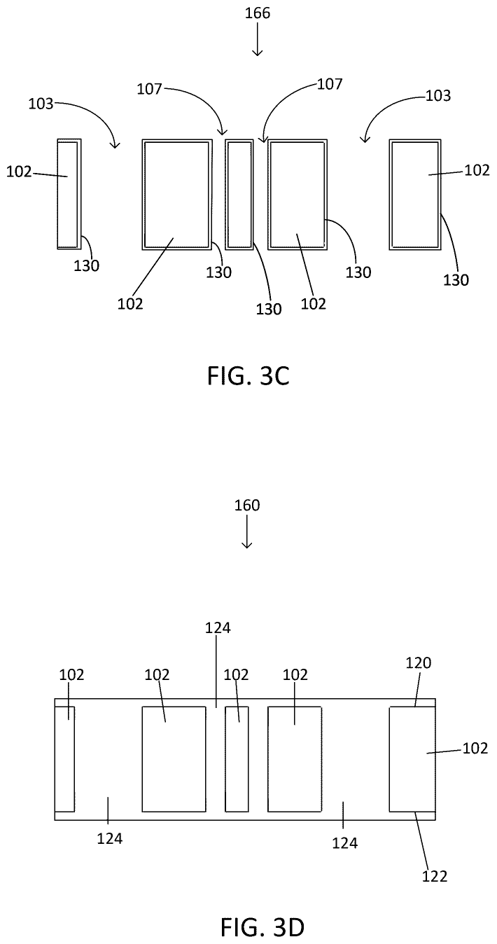

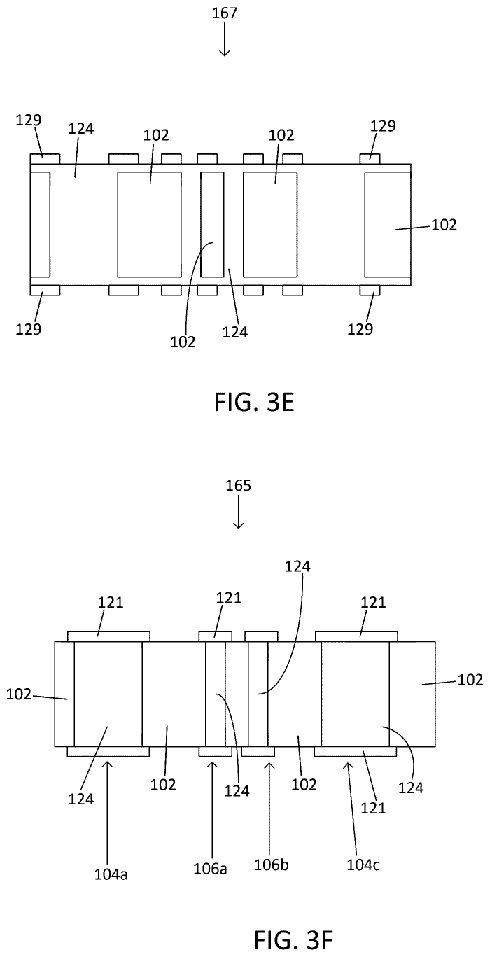

FIGS. 3A-3F depict methods of forming segmented annular through core metal ground structures which surround circular thru-core metal signal structures to form IC package devices by utilizing an electrolytic plating process subsequent to a conductive seed deposition within inner and outer TGVs. A faraday cage structure is formed having near zero spacing between individual segmented ground TGVs. The segmented annular TGV structures can replace portions of a glass core substrate, which improves thermal conductivity of the glass core substrate.

FIG. 3A depicts a cross-sectional view of a portion of a core substrate 102 comprising a layer of glass. In an embodiment, the core substrate 102 may comprise a thickness of between 500 microns to 1000 microns. In FIG. 3B, a process 160 may be employed wherein a plurality of first openings 103 may be formed and a plurality of second openings 107 may be formed. A first lateral width 105 of the first openings 103 may be greater than a second lateral width 109 of the second openings 107. In an embodiment, the first lateral width 105 may comprise 80 microns to 200 microns, and the second lateral width 109 may comprise 80 to 200 microns. In an embodiment, the process 160 may comprise any suitable etching process to remove glass, such as a laser removal process for example.

FIG. 3C depicts a cross-sectional view of a process 166, wherein a seed layer 130 may be formed on exposed surfaces of the substrate 102. In an embodiment, the seed layer 130 may comprise a thickness of about 10 nm to 10 um. In an embodiment, the seed layer 130 may comprise a conductive material such as copper or copper alloys.

FIG. 3D depicts a formation process 163 wherein a conductive material 124 is formed on the seed layer (which may be subsumed) within the first openings 103 and the second openings 107 of the substrate core 102. In an embodiment, the conductive formation process 163 may comprise an electrolytic plating process 163. In an embodiment, the conductive material 124 may be formed a distance above the first side 120 of the core substrate 102. In an embodiment, the conductive material 124 may comprise any suitable conductive material such as copper or copper alloys, for example.

FIG. 3E depicts a photoresist process 167 wherein photoresist 129 is formed and patterned on the surface of the conductive material 124 to define contacts 121 (FIG. 3F). Process 167 may comprise a subtractive etch lithographic process 167, in an embodiment. In this manner, outer TGV structures 104a, 104c and inner TGV structures 106a, 106b may be formed, similar to those depicted in FIG. 1C for example.

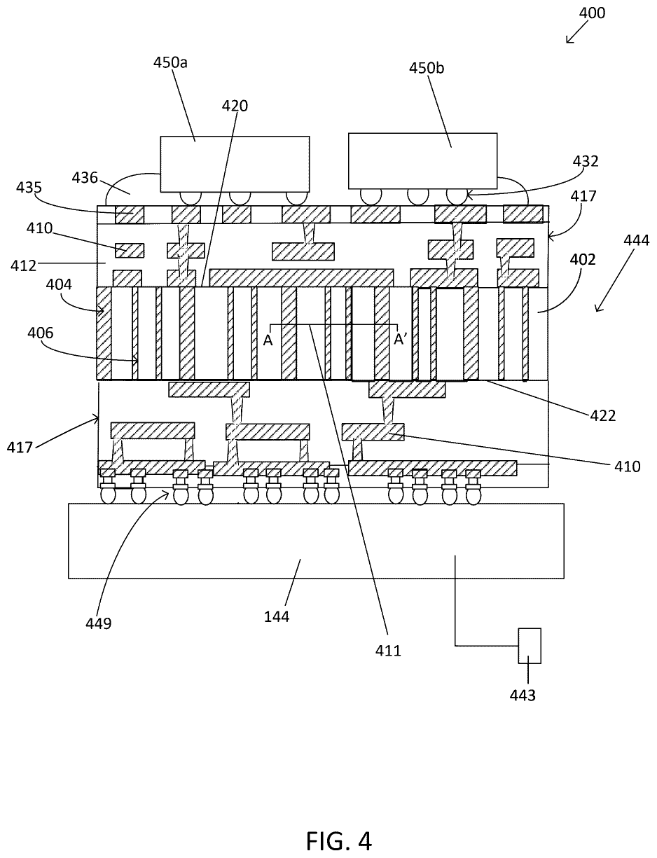

FIG. 4 depicts an IC package structure 400, such as a package structure including a core substrate 402 comprising a layer of glass. Signal TGV structures 406 and ground TGV structures 404 extend through the substrate core 402. A plan view through segment A-A′ 411 may be similar to the plan view depicted in FIG. 1A for example, wherein ground TGV segmented annular structures 404 surround signal TGV structures 106. Portions of the package structure 400 may be similar to the portions of the package structures depicted in FIG. 2G for example.

Buildup layers 417 are on first and second sides 420, 422 of the core substrate 402 wherein conductive structures 410 are dispersed within dielectric material 412. Dielectric material 412 may be formed from an epoxy based resin such as bisphenol A, epoxy resin, a bisphenol F epoxy resin, a novolac epoxy resin, an aliphatic epoxy resin, a glycidylamine epoxy resin, and a glycidylamine epoxy resin, or any other resin including one or more terminal epoxy groups.

TGVs 404, 406 extend through the core substrate 402 from a fist side 420 to a second side 422. TGVs 404, 406 are coupled to dies 450a, 450b. In some embodiments, the dies 450a, 450b may comprise chiplet structures which may comprise components of a system on a chip (SOC) structure. In an embodiment the core substrate 402 may include a portion of an interposer. TGVs 404, 406 may comprise a faraday cage structure wherein outer TGVs 406 comprise segmented annular segments which surround the inner TGVs 404. In an embodiment, the outer TGVs 406 comprise segmented ground structures and the TGVs 404 comprise circular signal structures. In an embodiment the TGV4s 404, 406 improve the signal loss of devices utilizing the package structure 400 of the embodiments herein.

Any number of die/devices may be coupled to the TGV's 404, 406. A package substrate 444 (comprising the substrate core 402 and build up layers 417) may be coupled to a board 144, such as a printed circuit board (PCB), in an embodiment. Semiconductor material (e.g., a silicon, gallium, indium, germanium, or variations or combinations thereof) and one or more insulating layers, such as organic based build up film, glass-reinforced epoxy, such as FR-4, polytetrafluor ethylene (Teflon), cotton-paper reinforced epoxy (CEM-3), phenolic-glass (G3), paper-phenolic (FR-1 or FR-2), poly ester-glass (CEM-5), or any other dielectric layer, may be used in the PCB and/or the package substrate 444.

Package substrate 444 may be fabricated using a bumpless buildup layer process (BBUL) or other techniques. A BBUL process includes one or more build-up layers formed around an element, such as a high density interconnect element or bridge die, as are known in the art. A micro via formation process, such as laser drilling, may form connections between build-up layers 417 and die bond pads 435. The build-up layers 417 may be formed using a high density integration patterning technology. The board 144 may be coupled to the package substrate 444 through solder structures 449 in an embodiment. A power supply 443, which may comprise any suitable power supply as known in the art, may be coupled to die 450a, 450b via IC package substrate 444, in an embodiment. Solder interconnect structures 432 may couple the die 450a, 450b to the package substrate 444. An underfill material 436 may surround the solder structures 432, in an embodiment.

Discussion now turns to operations for assembling and/or fabricating the discussed structures.

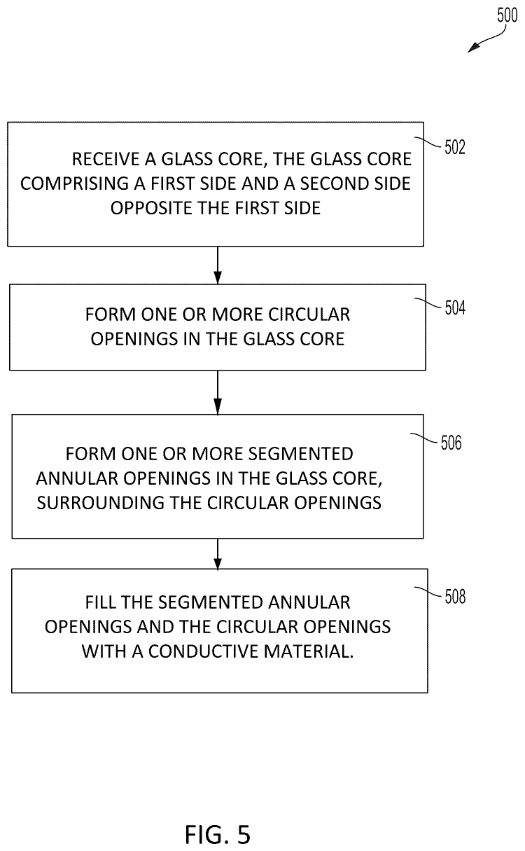

FIG. 5 is a flow chart of a process 500 of fabricating package structures, such as a package substrate comprising a glass core substrate, the glass core substrate having one or more segmented annular openings surrounding circular openings. The circular openings may comprise differential signal structures with the annular ring structures comprising a ring of ground structures around the signal circular openings. The segmented annular ring structures comprising a faraday cage around the signal circular openings. For example, process 500 may be used to fabricate any of the microelectronic IC package structures of FIGS. 1A-1C, for example.

As set forth in block 502, a glass core substrate is received comprising a layer of glass. In an embodiment, the glass layer may comprise one or more of aluminosilicate, borosilicate, an alumino borosilicate, silica, or a fused silica. In an embodiment, the layer of glass may comprise a first side and a second side opposite the first side.

As set forth in block 504, one or more circular openings may be formed in the glass core substrate to form signal through holes. In an embodiment, the one or more circular openings may be formed utilizing a wet etch process or a laser etch process. The one or more circular openings may comprise signal TGVs in an embodiment. The one or more circular openings may comprise a depth equal to a length of the glass core substrate. In an embodiment, the glass core substrate may comprise a length of 500 microns to about 1000 microns. In an embodiment, individual circular openings may comprise a diameter of about 10-20 microns but may comprise 80 to 200 microns in other embodiments. The diameter of the circular openings may be optimized for a particular application. A distance between adjacent circular openings may be between about 80 microns to about 200 microns but may be optimized according to a particular application.

As set forth in block 506, one or more segmented annular openings may be formed in the glass core substrate, surrounding the circular openings. his may be accomplished by utilizing a laser glass ablation process. In an embodiment, a length of the annular segments may be between 200 microns and 1000 microns, and wherein a distance between adjacent segments of the segmented annular openings may be between 5 microns and 20 microns but may vary depending upon the particular application.

As set forth in block 508, the segmented annular openings and the circular openings may be filled with a conductive material. In an embodiment, the openings may be filled with a metallic material, such as copper or copper alloy. A plating process may be utilized to fill the segmented annular openings and the circular openings with the conductive material.

Build-up layers may be formed on first and second sides of the glass core substrate. One or more die may be attached on the buildup layers to form a package structure such as is shown in FIG. 4 for example. The one or more die may comprise a central processing unit (CPU) or a field programmable gate array (FPGA) die, for example or may comprise any suitable logic die for the particular application. The one or more die may be attached utilizing any suitable die attach process, as are known in the art.

The embodiments herein enable through core structures that surpass less than 1 dB loss through a glass core substrate at 90 GHz, for example. This improvement also allows relaxation of the buildup material/design rule requirements for the packages described herein. Operating frequency or bandwidth targets can be expanded utilizing the embodiments herein. Thermal conductivity in the core substrate can be optimized to combat the challenge of limited x-y or even z-directional thermal transport in IC packages. Since the segmented annular structures replace larger portions of glass within the glass core substrate with copper, the package structures described herein possess superior thermal conductivity characteristics.

The use of bottom-up plating processes described herein to form segmented annular rings of grounded metal around HSIO thru holes reduces process sensitivity by balancing sidewall, conformal plating and fill plating to achieve desired pitch requirements for a particular application.

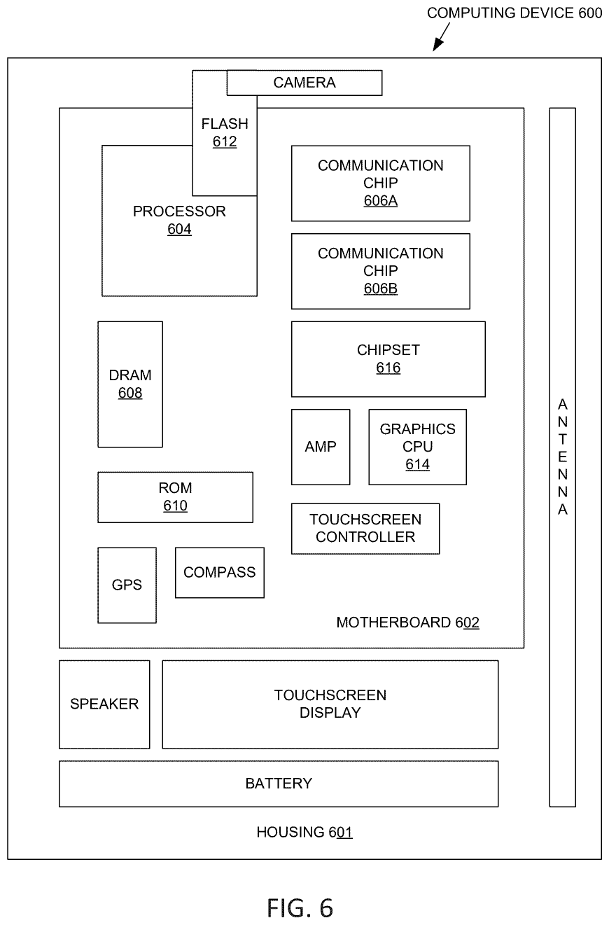

FIG. 6 illustrates an electronic or computing device 600 in accordance with one or more implementations of the present description. The computing device 600 may include a housing 601 having a board 602 disposed therein. The computing device 600 may include a number of integrated circuit components, including but not limited to a processor 604, at least one communication chip 606A, 606B, volatile memory 608 (e.g., DRAM), non-volatile memory 610 (e.g., ROM), flash memory 612, a graphics processor or CPU 614, a digital signal processor (not shown), a crypto processor (not shown), a chipset 616, an antenna, a display (touchscreen display), a touchscreen controller, a battery, an audio codec (not shown), a video codec (not shown), a power amplifier (AMP), a global positioning system (GPS) device, a compass, an accelerometer (not shown), a gyroscope (not shown), a speaker, a camera, and a mass storage device (not shown) (such as hard disk drive, compact disk (CD), digital versatile disk (DVD), and so forth). Any of the integrated circuit components may be physically and electrically coupled to the board 602. In some implementations, at least one of the integrated circuit components may be a part of the processor 604.

The communication chip enables wireless communications for the transfer of data to and from the computing device. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device may include a plurality of communication chips. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

The term “processor” may refer to any device or portion of a device that processes electronic data from registers and/or memory to transform that electronic data into other electronic data that may be stored in registers and/or memory. At least one of the integrated circuit components may include a core substrate with one or more individual annular segments separated by a distance surrounding one or more inner vias.

In various implementations, the computing device may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device may be any other electronic device that processes data.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure. It is understood that the subject matter of the present description is not necessarily limited to specific applications illustrated in FIGS. 1-6. The subject matter may be applied to other integrated circuit devices and assembly applications, as well as any appropriate electronic application, as will be understood to those skilled in the art.

The following examples pertain to further embodiments and specifics wherein the examples may be used anywhere in one or more embodiments, wherein a first example is an apparatus comprising an apparatus, comprising: a core substrate, wherein the core substrate comprises a layer of glass; a plurality of outer vias each extending through the layer of glass, wherein the outer vias each comprise a first lateral width, and wherein the outer vias each comprises individual annular segments separated by a distance; and one or more inner vias extending through the layer of glass adjacent to the outer vias, wherein the one or more inner vias comprise a second lateral width, wherein the first lateral width is greater than the second lateral width, and wherein the outer vias are located in a peripheral portion of the core substrate.

In second examples, the first example further comprising wherein the one or more inner vias are located in a central portion of the core substrate.

In third examples, wherein any of examples 1-2 further comprises wherein the core substrate is over a board, and wherein the one or more inner vias and the plurality of outer vias extend in an x-y plane and are parallel to the board.

In fourth examples, wherein example 3 further comprises wherein the individual annular segments comprise a length of 200 microns to 1000 microns and surround the one or more inner vias.

In fifth examples, wherein example 3 further comprises wherein the distance comprises between 10 microns and 50 microns.

In sixth examples, wherein any of examples 1-5 further comprises wherein there are four or more individual annular segments.

In seventh examples, wherein any of examples 1-6 further comprise wherein each of the one or more inner vias comprise a diameter of 80 microns to 200 microns.

In eighth examples, wherein any of examples 1-7 further comprise wherein the first lateral width comprises 80 to 200 microns and the second lateral width comprises 80 to 200 microns.

In ninth examples, wherein any of examples 1-8 further comprise wherein the one or more inner vias and the plurality of outer vias comprise through glass vias (TGVs) comprising a copper or a copper alloy, and wherein the layer of glass comprises one or more of aluminosilicate, borosilicate, an alumino borosilicate, silica, or a fused silica.

In tenth examples, wherein any of examples 1-9 further comprise wherein one or more integrated circuit (IC) die are coupled to the core substrate, wherein the one or more inner vias and the plurality of outer vias are coupled to the one or more IC die, and wherein a power supply is coupled to the one or more IC die.

In eleventh examples, wherein any of examples 1-9 further comprise wherein the one or more inner vias comprise one or more signal vias and the plurality of outer vias comprise a plurality of ground vias.

Example 12 is an apparatus comprising a first set of conductive vias comprising a circular shape; a second set of conductive vias surrounding the first set of conductive vias, the second set of conductive vias comprising a segmented annular ring shape; and a layer of glass surrounding the first set of conductive vias and the second set of conductive vias, the layer of glass comprising: a first side and a second side opposite the first side, wherein the first set of conductive vias and the second set of conductive vias extend between the first side and the second side of the layer of glass.

In thirteenth examples, wherein example 12 further comprises wherein a lateral width of the first set of conductive vias comprises between 10 microns and 20 microns, and wherein a lateral width of the second set of conductive vias comprises between 30 microns and 80 microns.

In fourteenth examples, wherein examples 12-13 further comprise wherein the layer of glass comprises a glass core, wherein the first set of conductive vias comprises one or more signal vias, and the second set of conductive vias comprises one or more ground vias.

In fifteenth examples, wherein examples 12-14 further comprise wherein the glass core is over a board, and wherein the first set of conductive vias and the second set of conductive vias extend in an x-y plane and are parallel to the board, wherein each segment of the second set of conductive vias comprises a length of 200 microns to 1000 microns.

In sixteenth examples, wherein examples 12-15 further comprise wherein the first set of conductive vias and the second set of conductive vias are on a build-up layer and are coupled to one or more die, wherein the one or more die are over the layer of glass.

Example 17 is a method comprising. receiving a glass core, the glass core comprising a first side and a second side opposite the first side; forming one or more circular openings in the glass core; forming two or more segmented annular openings in the glass core, surrounding the circular openings, wherein the circular openings and the segmented annular openings extend between the first side and the second side of the glass core; and filling the segmented annular openings and the circular openings with a conductive material.

In eighteenth examples, wherein example 17 further comprises wherein filling the segmented annular openings and the circular openings comprises forming a copper material or copper alloy material within the segmented annular openings and within the circular openings.

In nineteenth examples, wherein examples 17-18 further comprise wherein the glass core is over a board, wherein the segmented annular openings extend in an x-y plane and are parallel to the board, wherein the segmented annular openings comprise four or more individual adjacent segments, wherein the four or more individual adjacent segments are separated by a distance.

In twentieth examples, wherein example 19 further comprises wherein the one or more circular openings extend in an x-y plane and are parallel to the board, wherein a diameter of the one or more circular openings comprises between 80 microns to 200 microns and wherein a length of the individual adjacent segments comprises 200 microns to 1000 microns.

It will be recognized that principles of the disclosure are not limited to the embodiments so described but can be practiced with modification and alteration without departing from the scope of the appended claims. The above embodiments may include the undertaking only a subset of such features, undertaking a different order of such features, undertaking a different combination of such features, and/or undertaking additional features than those features explicitly listed. The scope of the embodiments should, therefore, be determined with reference to the appended claims, along with the full scope of equivalents to which such claims are entitled.

What is claimed is:

1. An apparatus, comprising:
a core substrate, wherein the core substrate comprises a layer of glass;
a plurality of outer vias each extending through the layer of glass, wherein the outer vias each comprise a first lateral width, and wherein the outer vias each comprises individual annular segments separated by a distance; and
one or more inner vias extending through the layer of glass adjacent to the outer vias, wherein the one or more inner vias comprise a second lateral width, wherein the first lateral width is greater than the second lateral width.

2. The apparatus of claim 1, wherein the one or more inner vias are located in a central portion of the core substrate.

3. The apparatus of claim 1, wherein the core substrate is over a board, and wherein the one or more inner vias and the plurality of outer vias extend in an x-y plane and are parallel to the board.

4. The apparatus of claim 3, wherein the individual annular segments comprise a length of 200 microns to 1000 microns and surround the one or more inner vias.

5. The apparatus of claim 3, wherein the distance comprises between 10 microns and 50 microns.

6. The apparatus of claim 1, wherein there are four or more individual annular segments.

7. The apparatus of claim 1, wherein each of the one or more inner vias comprise a diameter of 80 microns to 200 microns.

8. The apparatus of claim 1, wherein the first lateral width comprises 80 to 200 microns and the second lateral width comprises 80 to 200 microns.

9. The apparatus of claim 1, wherein the one or more inner vias and the plurality of outer vias comprise through glass vias (TGVs) comprising a copper or a copper alloy, and wherein the layer of glass comprises one or more of aluminosilicate, borosilicate, an alumino borosilicate, silica, or a fused silica.

10. The apparatus of claim 1, wherein one or more integrated circuit (IC) die are coupled to the core substrate, wherein the one or more inner vias and the plurality of outer vias are coupled to one or more IC die, and wherein a power supply is coupled to the one or more IC die.

11. The apparatus of claim 1, wherein the one or more inner vias comprise one or more signal vias and the plurality of outer vias comprise a plurality of ground vias.

12. An apparatus, comprising:
a first set of conductive vias comprising a circular shape;
a second set of conductive vias surrounding the first set of conductive vias, the second set of conductive vias comprising a segmented annular ring shape;
and
a layer of glass surrounding the first set of conductive vias and the second set of conductive vias, the layer of glass comprising:
a first side and a second side opposite the first side, wherein the first set of conductive vias and the second set of conductive vias extend between the first side and the second side of the layer of glass.

13. The apparatus of claim 12, wherein a lateral width of the first set of conductive vias comprises between 80 microns and 200 microns, and wherein a lateral width of the second set of conductive vias comprises between 80 microns and 200 microns.

14. The apparatus of claim 12, wherein the layer of glass comprises a glass core, wherein the first set of conductive vias comprises one or more signal vias, and the second set of conductive vias comprises one or more ground vias.

15. The apparatus of claim 14, wherein the glass core is over a board, and wherein the first set of conductive vias and the second set of conductive vias extend in an x-y plane and are parallel to the board, wherein each segment of the second set of conductive vias comprises a length of 200 microns to 1000 microns.

16. The apparatus of claim 12, wherein the first set of conductive vias and the second set of conductive vias are on a build-up layer and are coupled to one or more die, wherein the one or more die are over the layer of glass.

17. A method, comprising:
receiving a glass core, the glass core comprising a first side and a second side opposite the first side;
forming one or more circular openings in the glass core;
forming two or more segmented annular openings in the glass core, surrounding the circular openings, wherein the circular openings and the segmented annular openings extend between the first side and the second side of the glass core; and
filling the segmented annular openings and the circular openings with a conductive material.

18. The method of claim 17, wherein filling the segmented annular openings and the circular openings comprises forming a copper material or copper alloy material within the segmented annular openings and within the circular openings.

19. The method of claim 17, wherein the glass core is over a board, wherein the segmented annular openings extend in an x-y plane and are parallel to the board, wherein the segmented annular openings comprise four or more individual adjacent segments, wherein the four or more individual adjacent segments are separated by a distance.

20. The method of claim 19, wherein the one or more circular openings extend in an x-y plane and are parallel to the board, wherein a diameter of the one or more circular openings comprises 80 microns to 200 microns and wherein a length of the individual adjacent segments comprises 200 microns to 1000 microns.
